(19) United States
(12) Patent Application Publication
(10) Pub. No.: US 2012/0251737 A1
(43) Pub. Date: Oct. 4, 2012

(54) PLASMA-NITRIDING METHOD

(75) Inventors: Yoshinori OSAKI, Kurokaga-gun (JP); Takeshi Kuroda, Sendai City (JP)

(73) Assignee: TOKYO ELECTRON LIMITED, Tokyo (JP)

(21) Appl. No.: 13/436,006

(22) Filed: Mar. 30, 2012

(30) Foreign Application Priority Data
Mar. 31, 2011 (JP) 2011-080075

(51) Int. Cl. C23C 16/511

(52) U.S. Cl. 427/575

(57) ABSTRACT

A plasma-nitriding method for plasma-nitriding a silicon nitride film includes loading a target object into a processing chamber and mounting the target object on a mounting table; heating the target object; supplying a processing gas containing a nitrogen-containing gas and a rare gas into the processing chamber while introducing a microwave into the processing chamber, generating an electric field in the processing chamber, and generating a plasma by exciting the processing gas; and plasma-nitriding and modifying a silicon nitride film formed on the target object by the generated plasma. The silicon nitride film is a silicon nitride film formed at a film forming temperature ranging from 200° C. to 400° C. by an ALD method, and the silicon nitride film is plasma-nitrided at a processing temperature whose maximum is equal to the film forming temperature in the ALD method to form a silicon nitride film modified by a low-temperature nitrogen-containing plasma.

### CROSS-REFERENCE TO RELATED APPLICATIONS

This application claims priority to Japanese Patent Application No. 2011-080075 filed on Mar. 31, 2011, the entire contents of which are incorporated herein by reference.

### FIELD OF THE INVENTION

The present invention relates to a plasma-nitriding method can be used in manufacturing processes of various semiconductor devices.

### BACKGROUND OF THE INVENTION

A gate laminated structure of, e.g., a MOS structure is used in a semiconductor device such as DRAM. Generally, a cap film, a sidewall film or a spacer film is formed at an upper portion or a side portion of the gate laminated structure of this type. A silicon nitride film (SiN film) may be used as the cap film, the sidewall film or the spacer film. As a method for forming the SiN film, CVD is generally used, but there has been known a method called atomic layer deposition (ALD) or molecular layer deposition (MLD) (hereinafter, collectively referred to as “ALD method”) in which film formation can be achieved at a low temperature and the film thickness or film quality can be easily controlled.

In the ALD method, after a first reaction gas is adsorbed onto the surface of the substrate under a vacuum atmosphere, a second reaction gas is supplied, and single or multiple atomic layers or molecular layers are formed by a reaction between the gases. By performing this cycle many times, these layers are stacked, so that film formation is performed on the substrate. In the ALD method, it is possible to control the film thickness according to the number of cycles in a high precision, and achieve good in-plane uniformity of film quality. Further, the ALD method is effective to respond to the miniaturization of semiconductor devices. Recently, in order to reduce a thermal budget, it has been required to develop a technique for forming a silicon nitride film at a low temperature of, e.g., about 400° C. by the ALD method.

In Japanese Patent Applications Publication Nos. 2006-108493 (FIG. 3, etc.) and 2006-073758 (Paragraph [0052], etc.), it has been proposed that a plasma-nitriding process is performed on a silicon nitride film formed by the ALD method as a part of a gate insulating film of MOSFET. Further, it is aimed to improve the quality of the silicon nitride film formed by the ALD method and suppress nitrogen from diffusing and reaching an interface between the gate insulating film and silicon by the plasma-nitriding process, thereby reducing the gate leakage current and preventing degradation of the device characteristics.

Meanwhile, in a process of manufacturing a semiconductor device, a wet etching may be performed on the gate laminated structure having a cap film and/or a sidewall film, e.g., in order to manufacture a device in other portions of the substrate. Accordingly, an adequate etching resistance is required for the cap film and/or the sidewall film. However, as described above, the silicon nitride film formed by the ALD method at a low temperature of about 400° C. has unstable N—Si bonds in the film and a low etching resistance. Therefore, in case where etching is included in the semiconductor process, there is a problem that the cap and/or sidewall film are cut out and the functions of the cap film and/or the sidewall film are damaged.

### SUMMARY OF THE INVENTION

In view of the above, the present invention provides a method capable of improving an etching resistance of a silicon nitride film formed by a low temperature ALD method.

In accordance with an aspect of the present invention, there is provided a plasma-nitriding method for plasma-nitriding a silicon nitride film by using a plasma processing apparatus. The apparatus includes a processing chamber having an opening at its top; a mounting table, for mounting a target object having the silicon nitride film thereon, provided in the processing chamber; a heating unit for heating the target object; a microwave transmitting plate provided to face the mounting table, the microwave transmitting plate serving to close the opening of the processing chamber and transmit a microwave therethrough; a planar antenna disposed outside the microwave transmitting plate and having slots through which the microwave is introduced into the processing chamber; a gas inlet configured to introduce a processing gas into the processing chamber; and an exhaust unit configured to vacuum evacuate the processing chamber. The method includes loading the target object into the processing chamber and mounting the target object on the mounting table; heating the target object by the heating unit; supplying a processing gas including a nitrogen-containing gas and a rare gas into the processing chamber from the gas inlet while introducing the microwave into the processing chamber from the planar antenna through the microwave transmitting plate, generating an electric field in the processing chamber, and generating a plasma by exciting the processing gas; and plasma-nitriding and modifying the silicon nitride film formed on the target object by the generated plasma of the processing gas. The silicon nitride film is a silicon nitride film formed at a film forming temperature ranging from 200° C. to 400° C. by an ALD method, and the silicon nitride film is plasma-nitrided at a processing temperature whose maximum is equal to the film forming temperature in the ALD method to form a silicon nitride film modified by a low-temperature nitrogen-containing plasma.

### BRIEF DESCRIPTION OF THE DRAWINGS

The objects and features of the present invention will become apparent from the following description of embodiments, given in conjunction with the accompanying drawings, in which:

FIG. 1 is a cross-sectional view schematically showing a configuration of a plasma processing apparatus in accordance with a first embodiment of the present invention;

FIG. 2 shows a structure of a planar antenna;

FIG. 3 is an explanatory diagram showing a configuration example of a control unit;

FIGS. 4A to 4C explain steps of a plasma-nitriding method in accordance with the first embodiment of the present invention;

FIG. 5 schematically shows a configuration of a substrate processing system in accordance with the embodiments of the present invention;

FIG. 6 is a longitudinal cross-sectional view schematically showing a configuration of an ALD apparatus capable of forming a silicon nitride film at a low temperature;

FIG. 7 is a transverse cross-sectional view showing the ALD apparatus shown in FIG. 6; and

FIG. 8 is a graph showing wet etching rates of respective silicon nitride films for the comparison in a test example in accordance with a second embodiment of the present invention.

### DETAILED DESCRIPTION OF THE EMBODIMENTS

### First Embodiment

Hereinafter, a first embodiment of the present invention will be described with reference to the accompanying drawings which form a part hereof. A plasma-nitriding method of this embodiment includes performing a plasma-nitriding process on a target object in a processing chamber of a plasma processing apparatus by using a plasma of a processing gas containing a nitrogen-containing gas and a rare gas, the target object having a silicon nitride film formed by an ALD method.

### Plasma Processing Apparatus

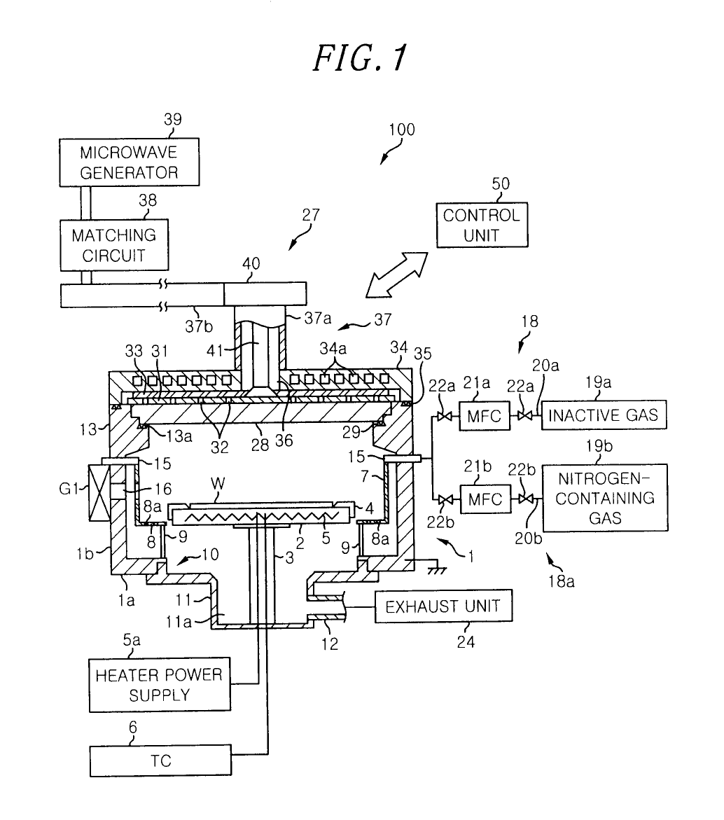

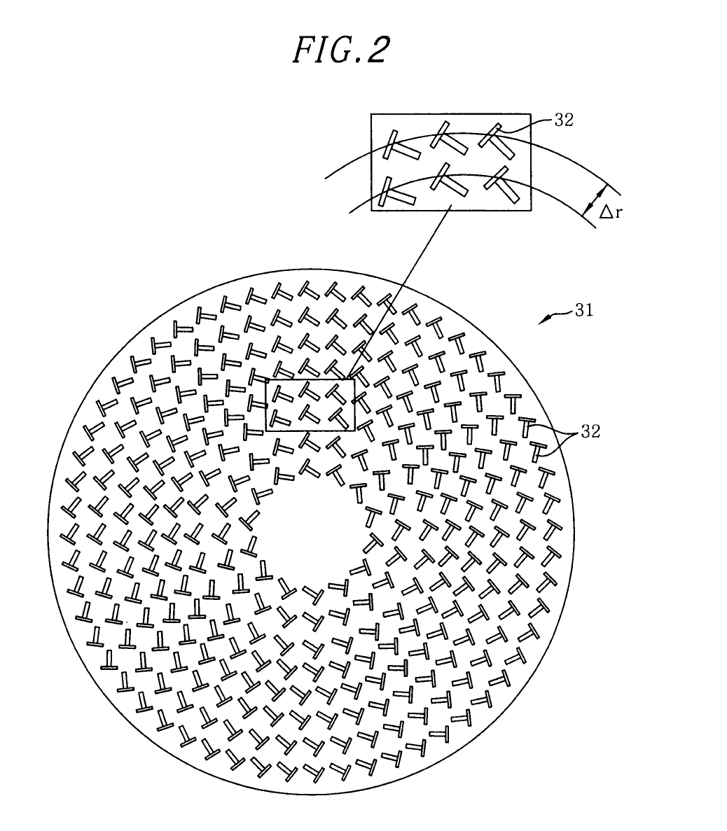

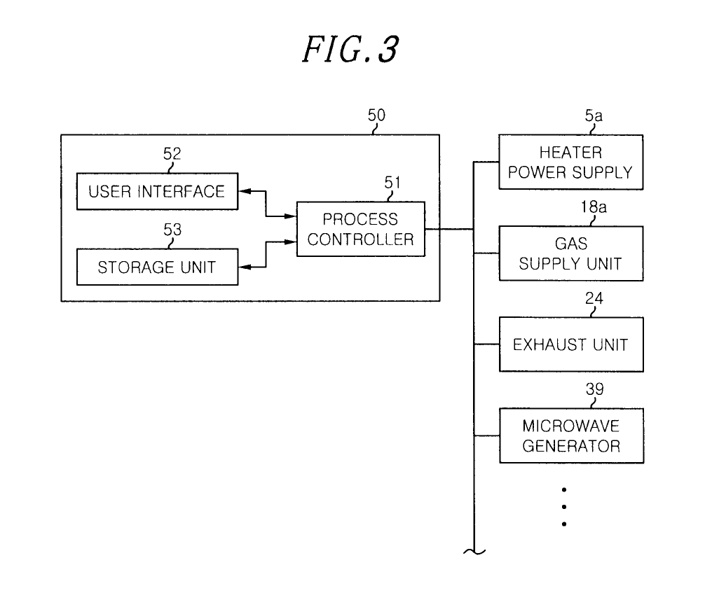

First, a plasma processing apparatus that can be used preferably in the plasma-nitriding method of this embodiment will be described with reference to FIGS. 1 to 3. FIG. 1 is a cross-sectional view schematically showing a configuration of a plasma processing apparatus 100 used in the plasma-nitriding method of this embodiment. FIG. 2 is a plan view showing a planar antenna of the plasma processing apparatus 100 shown in FIG. 1. FIG. 3 shows a configuration example of a control unit for controlling the plasma processing apparatus 100 shown in FIG. 1.

The plasma processing apparatus 100 is configured as a RLSA (Radial Line Slot Antenna) microwave plasma processing apparatus capable of generating a microwave-excited plasma with a high density and a low electron temperature by introducing a microwave into a processing chamber from a planar antenna, particularly, a RLSA, having a plurality of slot-shaped holes. In the plasma processing apparatus 100, a process can be performed by a plasma with a plasma density in a range from 1×10¹⁰ to 5×10¹²/cm³ and a low electron temperature in a range from 0.7 to 2 eV. Accordingly, the plasma processing apparatus 100 can be suitably used for the purpose of modifying the film quality of the silicon nitride film at a low temperature by plasma-nitriding.

The plasma processing apparatus 100 includes, as main elements, a air-tight processing chamber 1; a gas supply mechanism 18 for supplying a gas into the processing chamber 1; an exhaust unit 24 having a vacuum pump for vacuum evacuating the processing chamber 1; an microwave introducing unit 27 provided at the top of the processing chamber 1 to introduce a microwave into the processing chamber 1; and a control unit 50 for controlling each component of the plasma processing apparatus 100.

The processing chamber 1 is grounded and formed in an approximately cylindrical shape. Alternatively, the processing chamber 1 may be formed in a square tubular shape. The processing chamber 1 has a bottom wall la and a sidewall lb made of a metal such as aluminum or an alloy thereof.

A mounting table 2 for horizontally supporting a semiconductor wafer (hereinafter simply referred to as “wafer”) W is provided in the processing chamber 1. The mounting table 2 is formed of a material, e.g., ceramic such as AlN, with a high thermal conductivity. The mounting table 2 is supported by a cylindrical support member 3 extending upward from a central bottom portion of an exhaust chamber 11. The support member 3 is made of, e.g., ceramic such as AlN.

Further, a cover ring 4 is provided in the mounting table 2 to cover an outer peripheral portion of the mounting table 2 and guide the wafer W. The cover ring 4 is an annular member made of, e.g., a material such as quartz, AlN, Al₂O₃ and SiN. The cover ring 4 is preferably configured to cover a top surface and a side surface of the mounting table 2, thereby preventing metal contamination or the like.

Further, a resistance heater 5 is embedded as a temperature adjusting unit in the mounting table 2. The heater 5 is powered from a heater power supply 5a to heat the mounting table 2, thereby uniformly heating the wafer W serving as a target substrate to be processed.

Further, a thermocouple (TC) 6 is provided in the mounting table 2. The temperature of the mounting table 2 is measured by the thermocouple 6 so that the heating temperature of the wafer W can be controlled in a range from a room temperature to 900° C.

Further, wafer support pins (not shown) for supporting and lifting the wafer W are provided in the mounting table 2. Each of the wafer support pins is provided to protrude from and retreat into the top surface of the mounting table 2.

A cylindrical liner 7 made of quartz is provided on an inner periphery of the processing chamber 1. Further, an annular baffle plate 8 made of quartz and having a plurality of exhaust holes 8a is provided on an outer peripheral side of the mounting table 2 to uniformly evacuate the processing chamber 1. The baffle plate 8 is supported by support columns 9.

A circular opening 10 is formed in an approximately central portion of the bottom wall la of the processing chamber 1. The exhaust chamber 11 is provided in the bottom wall la to protrude downward and communicate with the opening 10. An exhaust pipe 12 is connected to the exhaust chamber 11, and is connected to the exhaust unit 24 through the exhaust pipe 12.

Provided at the top of the processing chamber 1 is a lid member 13 which has an opening and closing function and is formed in a frame shape having an opening at its center. Formed on an inner periphery of the opening of the lid member 13 are a stepped portion and an annular support portion 13a protruding toward the inside (space in the processing chamber).

A gas inlet 15 is provided at the sidewall lb of the processing chamber 1. The gas inlet 15 is connected to a gas supply unit 18a for supplying a nitrogen-containing gas or a plasma excitation gas. Further, the gas inlet 15 may be formed in a nozzle shape in the processing chamber 1. Besides, the gas inlet 15 may be formed in a shower head shape to face the mounting table 2 in the processing chamber 1.

Further provided in the sidewall lb of the processing chamber 1 are a loading/unloading port 16 through which the wafer W is loaded/unloaded between the plasma processing apparatus 100 and a vacuum side transfer chamber (not shown) adjacent to the plasma processing apparatus 100, and a gate valve G1 for opening and closing the loading/unloading port 16.

The gas supply mechanism 18 includes the gas supply unit 18a and the gas inlet 15. The gas supply unit 18a includes gas supply sources (e.g., an inactive gas supply source 19a and a nitrogen-containing gas supply source 19b); lines (e.g., gas lines 20a and 20b); flow rate controllers (e.g., mass flow controllers (MFCs) 21a and 21b); and valves (e.g., opening and closing valves 22a and 22b). Further, the gas supply unit 18a may further includes, as a gas supply source (not shown) other than the above-mentioned gas supply sources, e.g., a purge gas supply source or the like used when changing the atmosphere in the processing chamber 1. Furthermore, the gas supply mechanism 18 may use an external gas supply device by connecting it to the gas inlet 15 to perform the gas supply instead of employing components included in the plasma processing apparatus 100.

For example, N₂ gas, rare gas or the like may be used as an inactive gas. For example, Ar gas, Kr gas, Xe gas, He gas or the like may be used as the rare gas. Among them, particularly, Ar gas or He gas is preferably used. For example, N₂, NO, NO₂, NH₃ or the like may be used as a nitrogen-containing gas for a plasma-nitriding process.

The inactive gas and the nitrogen-containing gas are respectively supplied to the gas inlet 15 from the inactive gas supply source 19a and the nitrogen-containing gas supply source 19b of the gas supply unit 18a through the gas lines 20a and 20b, and are introduced into the processing chamber 1 from the gas inlet 15. Provided in each of the gas lines 20a and 20b connected to the corresponding gas supply source are a pair of opening and closing valves 22a(22b) and a mass flow controller 21a(21b) located between the opening and closing valves 22a(22b). By the configuration of the gas supply unit 18a, it is possible to switch the supplied gas or control a flow rate of the supplied gas.

The exhaust unit 24 includes the vacuum pump as described above. The vacuum pump is configured as a high speed vacuum pump, e.g., a turbo molecular pump or the like. The vacuum pump is connected to the exhaust chamber 11 of the processing chamber 1 through the exhaust pipe 12. The gas in the processing chamber 1 uniformly flows in a space 11a of the exhaust chamber 11, and the gas is exhausted from the space 11a through the exhaust pipe 12 by operating the vacuum pump. Accordingly, an internal pressure of the processing chamber 1 can be rapidly reduced to a predetermined vacuum level of, e.g., 0.133 Pa.

Next, a configuration of the microwave introducing unit 27 will be described. The microwave introducing unit includes, as main elements, a microwave transmitting plate 28; a planar antenna 31; a slow-wave member 33; a cover member 34; a waveguide 37; a matching circuit 38 and a microwave generator 39.

The microwave transmitting plate 28, which serves to transmit a microwave, is disposed on the support portion 13a protruding inward in the lid member 13. The microwave transmitting plate 28 is made of a dielectric material, e.g., ceramic such as quartz, Al₂O₃, AlN or the like. A seal member 29 is provided to airtightly seal a gap between the microwave transmitting plate 28 and the support portion 13a, thereby maintaining airtightness of the processing chamber 1.

The planar antenna 31 is disposed on the microwave transmitting plate 28 to face the mounting table 2. The planar antenna 31 has a disc shape. Further, the planar antenna 31 may have, e.g., a rectangular plate shape without being limited to a disc shape. The planar antenna 31 is suspended and fixed on an upper end of the lid member 13.

The planar antenna 31 is formed of, e.g., a copper plate or an aluminum plate which is plated with gold or silver. The planar antenna 31 has a plurality of slot-shaped microwave radiation holes 32 through which the microwave is radiated. The microwave radiation holes 32 are formed in a specific pattern to extend through the planar antenna 31.

Each of the microwave radiation holes 32 has, e.g., an elongated rectangular shape (slot shape) as shown in FIG. 2. Further, generally, the adjacent microwave radiation holes 32 are arranged in a “T” shape. The microwave radiation holes 32 which are combined in groups in a specific shape (e.g., T shape) are wholly arranged in a concentric circular pattern.

A length and an arrangement interval of the microwave radiation holes 32 are determined based on the wavelength (λg) of the microwave in the waveguide 37. For example, the microwave radiation holes 32 are arranged at the arrangement interval ranging from λg/4 to λg. In FIG. 2, the arrangement interval between the adjacent microwave radiation holes 32 formed in the concentric circular pattern is represented as Δr. Further, the microwave radiation holes 32 may have another shape such as a circular shape or a circular arc shape. Moreover, the microwave radiation holes 32 may be arranged in another pattern, e.g., a spiral or a radial pattern without being limited to the concentric circular pattern.

The slow-wave member 33 having a larger dielectric constant than that of the vacuum is disposed on an upper surface of the planar antenna 31. Since the microwave has a longer wavelength in the vacuum, the slow-wave member 33 functions to shorten the wavelength of the microwave to stably adjust the plasma. For example, quartz, polytetrafluoroethylene resin, polyimide resin or the like may be used as the material of the slow-wave member 33.

Further, the planar antenna 31 may be in contact with or separated from the microwave transmitting plate 28, but it is preferable that the planar antenna 31 is in contact with the microwave transmitting plate 28. Further, the slow-wave member 33 may be in contact with or separated from the planar antenna 31, but it is preferable that the slow-wave member 33 is in contact with the planar antenna 31.

The cover member 34 is provided at the top of the processing chamber 1 to cover the planar antenna 31 and the slow-wave member 33. The cover member 34 is made of a metal material such as aluminum and stainless steel. A flat waveguide is constituted by the cover member 34 and the planar antenna 31. A seal member 35 is provided to seal a gap between an upper end of the lid member 13 and the cover member 34. Further, the cover member 34 has a cooling water passage 34a formed therein. The cover member 34, the slow-wave member 33, the planar antenna 31 and the microwave transmitting plate 28 may be cooled by flowing a cooling water through the cooling water passage 34a. Further, the cover member 34 is grounded.

An opening 36 is formed in a central portion of an upper wall (ceiling) of the cover member 34. The opening 36 is connected to one end of the waveguide 37. The microwave generator 39 for generating a microwave is connected to the other end of the waveguide 37 via the matching circuit 38.

The waveguide 37 includes a coaxial waveguide 37a having a circular cross sectional shape, which extends upward from the opening 36 of the cover member 34; and a rectangular waveguide 37b, which is connected to an upper end of the coaxial waveguide 37a via a mode converter 40 and extended in a horizontal direction. The mode converter 40 functions to convert a microwave propagating in a TE mode in the rectangular waveguide 37b into a TEM mode microwave.

An internal conductor 41 extends through the center of the coaxial waveguide 37a. A lower end of the internal conductor 41 is connected and fixed to a central portion of the planar antenna 31. By this structure, the microwave is efficiently, uniformly and radially propagated to the flat waveguide constituted by the cover member 34 and the planar antenna 31 through the internal conductor 41 of the coaxial waveguide 37a. Then, the microwave is introduced into the processing chamber through the microwave radiation holes (slots) 32 of the planar antenna 31, thereby generating a plasma.

By the microwave introducing unit 27 having the above configuration, the microwave generated in the microwave generator 39 is propagated to the planar antenna 31 through the waveguide 37, and introduced into the processing chamber 1 through the microwave transmitting plate 28. Further, the microwave preferably has a frequency of, e.g., 2.45 GHz, but the frequency of the microwave may be 8.35 GHz, 1.98 GHz or the like.

Each component of the plasma processing apparatus 100 is connected to and controlled by the control unit 50. The control unit 7 has a computer. For example, as shown in FIG. 3, the control unit 50 includes a process controller 51 having a CPU; and a user interface 52 and a storage unit 53, which are connected to the process controller 51. The process controller 51 serves to integratedly control respective components (e.g., the heater power supply 5a, the gas supply unit 18a, the exhaust unit 24, the microwave generator 39 and other units) associated with the process conditions such as temperature, pressure, gas flow rate, microwave output and the like in the plasma processing apparatus 100.

The user interface 52 includes a keyboard through which a process operator performs, e.g., an input operation of commands in order to manage the plasma processing apparatus 100; a display for visually displaying an operational status of the plasma processing apparatus 100; and the like. Further, the storage unit 53 stores a recipe including process condition data or control programs (software) for performing various processes in the plasma processing apparatus 100 under the control of the process controller 51.

Further, if necessary, a certain recipe is retrieved from the storage unit 53 in accordance with instructions inputted through the user interface 52 and executed by the process controller 51. Accordingly, a desired process is performed in the processing chamber 1 of the plasma processing apparatus 100 under the control of the process controller 51. The recipe including process condition data or control programs may be stored in a computer-readable storage medium (e.g., CD-ROM, hard disk, flexible disk, flash memory, DVD, blue-ray disc and the like), or transmitted at any time from other devices via, e.g., a dedicated line to be available online.

In the plasma processing apparatus 100 having the above configuration, a plasma process can be performed at a low temperature of 600° C. or lower without causing damage to a base layer or the like. Accordingly, by using the plasma processing apparatus 100, plasma modification can be effectively performed on a silicon nitride film formed by a low temperature ALD method at a temperature that is equal to or smaller than a film forming temperature in the ALD method. Further, since the plasma processing apparatus 100 has an excellent plasma uniformity, in-plane uniformity of processing may be achieved even on a large-sized wafer W having a diameter of, e.g., 300 mm or more.

### Plasma-Nitriding Method

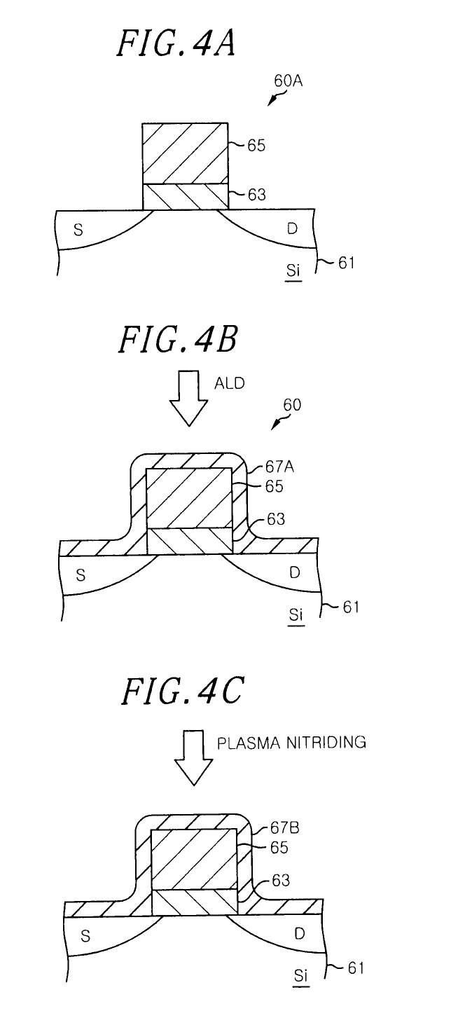

Next, a plasma-nitriding method which is performed in the plasma processing apparatus 100 will be described with reference to FIGS. 4A to 4C. FIGS. 4A to 4C are cross-sectional views showing the vicinity of the surface of the wafer W for explaining steps of the plasma-nitriding method of this embodiment. As a general example of the plasma-nitriding method of this embodiment, nitriding of a spacer film of a laminated MOS structure 60 will be exemplarily described.

The laminated MOS structure 60 is used as part of, e.g., a transistor such as a MOSFET, a MOS semiconductor memory or the like. Further, the plasma-nitriding method of this embodiment may be applied to a spacer film, a liner film, a sidewall film, a cap film or the like covering a semiconductor memory device such as a phase change memory and magnetoresistive random access memory without being limited to the laminated MOS structure. Further, the plasma-nitriding method of this embodiment may be applied to a spacer film, a liner film or the like of, e.g., a bit line of a DRAM.

First, a target wafer W to be processed is prepared. As shown in FIGS. 4A and 4B, a laminated structure 60A in which a silicon substrate 61, an insulating film 63, and an electrode layer 65 are sequentially stacked is formed on the wafer W. The laminated MOS structure 60 obtained by depositing a spacer film 67A serving as a silicon nitride film on the wafer W by the ALD method is a target object of the plasma-nitriding method of this embodiment.

In each of the laminated structures 60 and 60A, the insulating film 63 and the electrode layer 65 have been patterned in a predetermined shape. The insulating film 63 is, e.g., a silicon oxide film, a silicon nitride film, a silicon nitride oxide film, a high-dielectric constant (high-k) film or the like. The electrode layer 65 may be formed of, e.g., a metal such as Al, Ti, W, Ni and Co, a metal silicide thereof or the like. The spacer film 67A may be formed at a low temperature in a range from, e.g., 200° C. to 400° C. by the ALD method as described below. Further, in FIGS. 4A to 4C, ‘S’ and ‘D’ represent source and drain respectively.

Then, as shown in FIGS. 4B and 4C, the spacer film 67A is plasma-nitrided by using the plasma processing apparatus 100. Reference numeral 67B denotes the spacer film after plasma-nitriding. By plasma-nitriding, compared to the spacer film 67A, a nitrogen concentration of the spacer film 67B is increased (i.e., increase in Si—N bonds), the density of the film is increased, thereby improving the resistance to wet etching.

### Plasma-Nitriding Procedures

A sequence of the plasma-nitriding process is as follows. First, the target wafer W to be processed is loaded into the plasma processing apparatus 100, and mounted on the mounting table 2. Then, e.g., Ar gas and N₂ gas are respectively introduced into the processing chamber 1 at predetermined flow rates from the inactive gas supply source 19a and the nitrogen-containing gas supply source 19b of the gas supply unit 18a through the gas inlet 15 while vacuum evacuating the processing chamber 1 of the plasma processing apparatus 100. In this way, the internal pressure of the processing chamber 1 is adjusted to a predetermined level.

Then, the microwave of a predetermined frequency (e.g., 2.45 GHz) generated in the microwave generator 39 is transmitted to the waveguide 37 via the matching circuit 38. The microwave transmitted to the waveguide 37 sequentially passes through the rectangular waveguide 37b and the coaxial waveguide 37a, and is supplied to the planar antenna 31 through the internal conductor 41. That is, the microwave propagates in a TE mode in the rectangular waveguide 37b, and the TE mode microwave is converted into a TEM mode microwave by the mode convertor 40.

The TEM mode microwave propagates in the flat waveguide constituted by the cover member 34 and the planar antenna 31 through the coaxial waveguide 37a. Then, the microwave is radiated to the space above the wafer W in the processing chamber 1, through the microwave transmitting plate 28, from the microwave radiation holes 32 formed in a slot shape to pass through the planar antenna 31. The output of the microwave may be selected in a range from 1000 W to 5000 W, when the wafer W having a diameter of, e.g., 200 mm or more is processed, so that the power density is appropriate for the purpose.

An electromagnetic field is generated in the processing chamber 1 by the microwave radiated into the processing chamber 1 from the planar antenna 31 through the microwave transmitting plate 28, and Ar gas and N₂ gas are converted into a plasma. At this time, the microwave is radiated through the microwave radiation holes 32 of the planar antenna 31, thereby generating a plasma having a high density in a range from approximately 1×10¹⁰ to 5×10¹²/cm³ and a low electron temperature of approximately 1.2 eV or less in the vicinity of the wafer W. As for the plasma generated as described above, it is possible to reduce damage to a base film due to ions in the plasma. Further, a plasma-nitriding process is performed on the silicon nitride film of the surface of the wafer W by action of active species in the plasma. That is, the spacer film 67A of the wafer W is nitrided, thereby forming a dense spacer film 67B.

After forming the spacer film 67B as described above, the wafer W is unloaded from the plasma processing apparatus 100, and the process for one wafer W is completed.

### Plasma-Nitriding Conditions

It is preferable to use a gas containing a rare gas and nitrogen-containing gas as a processing gas of the plasma-nitriding process. It is preferable that Ar gas is used as the rare gas and N₂ gas is used as the nitrogen-containing gas. In this case, a ratio of the volumetric flow rate of N₂ gas to the total volumetric flow rate of the processing gas (percentage of a flow rate of N₂ gas/the total flow rate of the processing gas) is preferably in a range from 5% to 30%, or more preferably in a range from 10% to 30%, in order to form a dense film with an excellent resistance to wet etching by increasing the nitrogen concentration in the spacer film 67B. In the plasma-nitriding process, it is preferable to set the flow rate ratio, for example, such that the flow rate of Ar gas ranges from 500 mL/min (sccm) to 2000 mL/min (sccm) and the flow rate of N₂ gas ranges from 100 mL/min (sccm) to 400 mL/min (sccm).

Further, the processing pressure is preferably in a range, e.g., from 1.3 Pa to 67 Pa, or more preferably in a range from 1.3 Pa to 40 Pa, in order to form a dense film with an excellent resistance to wet etching by increasing the nitrogen concentration in the spacer film 67B. If the processing pressure exceeds 67 Pa in the plasma-nitriding process, since the plasma contains mainly radical components as active species for nitriding and less ion components, the nitriding rate decreases and the dose of nitrogen also decreases.

The microwave power density is preferably in a range from 0.5 W/cm² to 2.5 W/cm², or more preferably in a range from 0.5 W/cm² to 2.0 W/cm², and most preferably in a range from 0.7 W/cm² to 1.5 W/cm², in order to enhancing the nitriding rate by efficiently generating active species in the plasma. Here, the microwave power density indicates the microwave power per each 1 cm² area of the microwave transmitting plate 28 (hereinafter, this is true). For example, when the wafer W having a diameter of 200 mm or more is processed, the microwave power is preferably in a range from 1000 W to 5000 W.

The processing temperature in the plasma-nitriding process is set to be equal to or lower than the film forming temperature of the silicon nitride film (spacer film 67A). If the film forming temperature of the silicon nitride film formed by the ALD method is equal to or lower than, e.g., 400° C., the heating temperature of the wafer W also has a maximum of 400° C. Specifically, the temperature of the mounting table 2 is set, for example, such that the temperature of the wafer W is preferably in a range from 200° C. to 400° C., or more preferably in a range from 300° C. to 400° C. By performing the plasma-nitriding process on the silicon nitride film formed by the low temperature ALD method or the like at a low temperature that is equal to or lower than its deposition temperature, it is possible to reduce a thermal budget and maintain a thermal resistance to the heat generated in a subsequent step. Also, in a heat sensitive semiconductor process, it is possible to suppress, e.g., diffusion of atoms.

Further, the processing time of the plasma-nitriding process is not particularly limited, but is preferably in a range, e.g., from 60 seconds to 600 seconds, or more preferably in a range from 120 seconds to 240 seconds, in order to form a dense film with an excellent resistance to wet etching by increasing the nitrogen concentration in the spacer film 67B.

The above conditions are stored as a recipe in the storage unit 53 of the control unit 50. The process controller 51 reads the recipe and transmits a control signal to each component (e.g., the gas supply unit 18a, the exhaust unit 24, the microwave generator 39, the heater power supply 5a and the like) of the plasma-nitriding apparatus 1, thereby achieving the plasma-nitriding process under the desired conditions.

In accordance with the plasma-nitriding method of this embodiment, the spacer film 67A formed by the low temperature ALD method can be modified by the nitrogen-containing plasma at a temperature that is equal or to lower than its film forming temperature, thereby forming the spacer film 67B with an improved density. Since the spacer film 67B has a high resistance to wet etching, it is possible to suppress a reduction of the spacer film 67B even though the wet etching is performed in a semiconductor process. Further, since the plasma-nitriding process is performed at a processing temperature that is equal to lower than the maximum of the ALD method, it is possible to reduce the thermal budget.

Thus, in a manufacturing process of various semiconductor devices, a low-temperature nitrogen-containing plasma modified silicon nitride film obtained by modifying the silicon nitride film formed at a low temperature by the low-temperature nitrogen-containing plasma in accordance with this embodiment can be employed for a spacer film, a liner film, a sidewall film and a cap film in a semiconductor device of, e.g., a DRAM, a logic device, or a semiconductor memory device such as a phase change memory (PRAM), a resistive memory (ReRAM) and a magnetoresistive memory (MRAM), thereby increasing reliability of the semiconductor device.

### Substrate Processing System

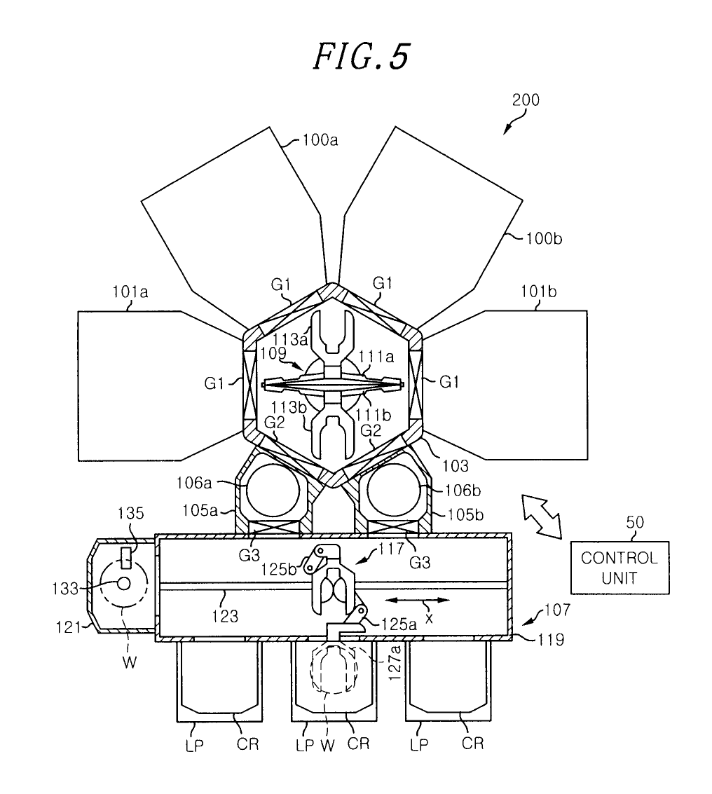

Next, a substrate processing system capable of being suitably used in the plasma-nitriding method of this embodiment will be described. FIG. 5 schematically shows a configuration of a substrate processing system 200 configured such that the silicon nitride film is formed on the wafer W by the ALD method and the plasma-nitriding process is performed under vacuum conditions. The substrate processing system 200 is configured as a cluster tool having a multi-chamber structure.

The substrate processing system 200 includes, as main elements, four process modules 100a, 100b, 101a and 101b for performing various processes on the wafer W; a vacuum side transfer chamber 103 connected to the process modules 100a, 100b, 101a and 101b via gate valves G1; two load-lock chambers 105a and 105b connected to the vacuum side transfer chamber 103 via gate valves G2; and a loader unit 107 connected to the load-lock chambers 105a and 105b via gate valves G3.

The four process modules 100a, 100b, 101a and 101b may perform the same process or different processes on the wafer W. In this embodiment, the process modules 100a and 100b perform film formation of the spacer film 67A by the ALD method. That is, each of the process modules 100a and 100b is configured as a single-wafer ALD apparatus. A description of a specific configuration of the single-wafer ALD apparatus will be omitted. Meanwhile, in the process modules 101a and 101b, the spacer film 67A is modified into the dense spacer film 67B by plasma-nitriding. That is, each of the process modules 101a and 101b is configured as the plasma processing apparatus 100.

Provided in the vacuum side transfer chamber 103 capable of being vacuum evacuated is a transfer unit 109 serving as a first substrate transfer unit for transferring the wafer W to/from the process modules 100a, 100b, 101a and 101b and the load-lock chambers 105a and 105b. The transfer unit 109 has a pair of transfer arms 111a and 111b arranged to face each other. Each of the transfer arms 111a and 111b is configured to be extensible/contractible and rotatable around the same rotation axis. Further, forks 113a and 113b each mounting and holding the wafer W are provided at the tips of the transfer arms 111a and 111b, respectively. While the wafer W is mounted on the forks 113a and 113b, the transfer unit 109 performs transfer of the wafer W between the process modules 100a, 100b, 101a and 101b, or between the process modules 100a, 100b, 101a and 101b and the load-lock chambers 105a and 105b.

Mounting tables 106a and 106b each for mounting the wafer W thereon are respectively provided in the load-lock chambers 105a and 105b. Each of the load-lock chambers 105a and 105b are configured to be switchable between a vacuum state and an atmospheric open state. The delivery of the wafer W is carried out between the vacuum side transfer chamber 103 and an atmospheric side transfer chamber 119 (to be described later) through the mounting tables 106a and 106b of the load-lock chambers 105a and 105b.

The loader unit 107 includes the atmospheric side transfer chamber 119 in which a transfer unit 117 is provided as a second substrate transfer unit for transferring the wafer W; three load ports LP arranged adjacent to one side of the atmospheric side transfer chamber 119; and an orienter 121 disposed adjacent to another side of the atmospheric side transfer chamber 119 to serve as a position measuring device for measuring the position of the wafer W.

The atmospheric side transfer chamber 119 includes a circulating unit (not shown) for forming a downflow of, e.g., a nitrogen gas or a clean air to maintain a clean environment. The atmospheric side transfer chamber 119 has a rectangular shape in the plan view, and a guide rail 123 is provided therein in a longitudinal direction thereof. The transfer unit 117 is slidably supported on the guide rail 123. That is, the transfer unit 117 is configured to be movable in an X direction along the guide rail 123 by a drive mechanism (not shown).

The transfer unit 117 has a pair of transfer arms 125a and 125b arranged vertically in two stages. Each of the transfer arms 125a and 125b is configured to be extensible/contractible and rotatable. Further, forks 127a and 127b each serving as a holding member for mounting and holding the wafer W are provided at the tips of the transfer arms 125a and 125b, respectively. While the wafer W is mounted on the forks 127a and 127b, the transfer unit 117 performs transfer of the wafer W between wafer cassettes CR of the load ports LP, the load-lock chambers 105a and 105b and the orienter 121.

The load ports LP are configured to mount wafer cassettes CR thereon. The wafer cassettes CR are configured to accommodate a plurality of wafers W in multiple stages at equal intervals.

The orienter 121 includes a rotation plate 133 which is rotated by a drive motor (not shown); and an optical sensor 135 provided at an outer periphery of the rotation plate 133 to detect an edge of the wafer W.

### Wafer Processing Procedures

In the substrate processing system 200, the silicon nitride film is formed on the wafer W by the ALD method and the plasma-nitriding process is performed by the following steps. First, one wafer W is unloaded from the wafer cassettes CR of the load ports LP by using one of the forks 127a and 127b of the transfer unit 117 of the atmospheric side transfer chamber 119. After position alignment is performed in the orienter 121, the wafer W is loaded into the load-lock chamber 105a (or 105b). The load-lock chamber 105a (or 105b) in which the wafer W has been mounted on the mounting table 106a (or 106b) is evacuated to vacuum after closing the gate valve G3. Then, the gate valve G2 is opened, and the wafer W is transferred from the load-lock chamber 105a (or 105b) by the forks 113a and 113b of the transfer unit 109 in the vacuum side transfer chamber 103.

The wafer W transferred from the load-lock chamber 105a (or 105b) by the transfer unit 109 is first loaded into one of the process modules 100a and 100b. After closing the gate valve G1, the deposition process of the spacer film 67A is performed on the wafer W by the ALD method.

Then, the gate valve G1 is opened, and the wafer W on which the spacer film 67A has been formed is loaded into one of the process modules 101a and 101b from the process module 100a (or 100b) in a vacuum state by the transfer unit 109. Then, after closing the gate valve G1, the plasma-nitriding process is performed on the wafer W such that the spacer film 67A is plasma-nitrided and modified into the spacer film (modified spacer film) 67B.

Then, the gate valve G1 is opened, and the wafer W on which the spacer film 67B has been formed is unloaded from the process module 101a (or 101b) in a vacuum state and loaded into the load-lock chamber 105a (or 105b) by the transfer unit 109. Then, the processed wafer W is received in the wafer cassettes CR of the load ports LP in reverse order to the above, thereby completing processing of one wafer W in the substrate processing system 200. arrangement of processing units in the substrate processing system 200 may be changed if corresponding processes can be efficiently performed. Further, the number of the process modules in the substrate processing system 200 may be five or more without being limited to four.

### ALD Apparatus

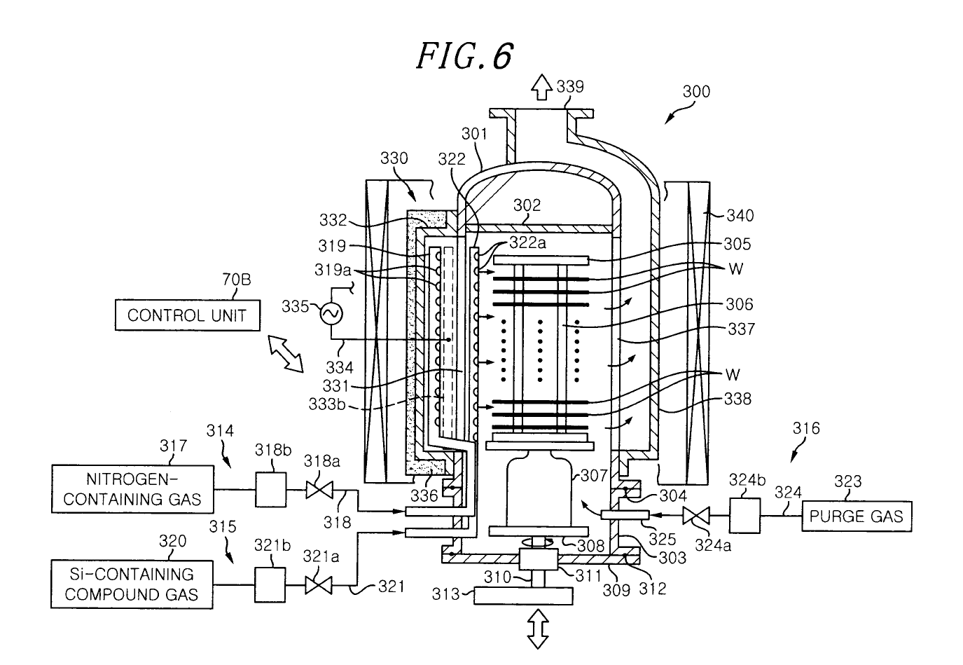

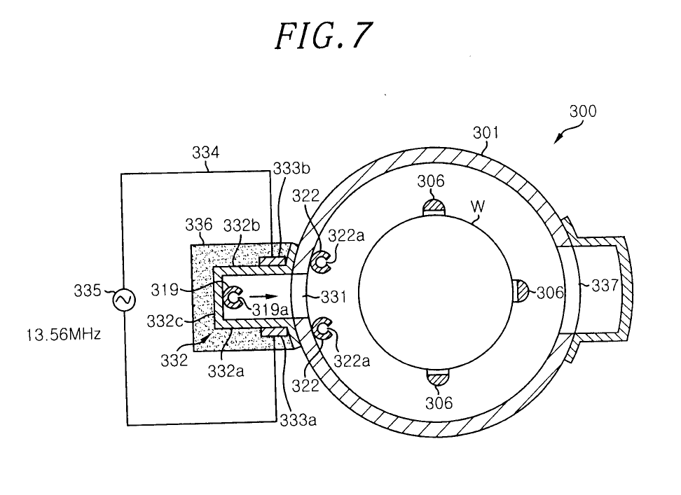

The silicon nitride film to be plasma-nitrided may be deposited by using a separate ALD apparatus different from the plasma processing apparatus 100 without being limited to a case of using the substrate processing system 200 shown in FIG. 5. For example, an ALD apparatus capable of efficiently forming a silicon nitride film at a low temperature of 400° C. or lower will be described with reference to FIGS. 6 and 7. FIG. 6 is a longitudinal cross-sectional view schematically showing a configuration of a batch type ALD apparatus 300 that can be preferably used when a silicon nitride film to be processed is formed in this embodiment. FIG. 7 is a transverse cross-sectional view schematically showing the configuration of the ALD apparatus 300. In FIG. 7, a heating unit is omitted.

As shown in FIGS. 6 and 7, the ALD apparatus 300 includes a cylindrical processing chamber 301 having an open bottom end and a closed top end. The processing chamber 301 is formed of, e.g., quartz. Provided at the top of the processing chamber 301 is a ceiling plate 302 formed of, e.g., quartz. Further, the opening of the bottom end of the processing chamber 301 is connected to a cylindrical manifold 303 made of, e.g., stainless steel. A seal member 304 such as an O ring is provided in a connecting portion between the processing chamber 301 and the manifold 303 to maintain airtightness therein.

The manifold 303 supports the bottom end of the processing chamber 301. From the bottom of the manifold 303, a wafer boat 305 made of quartz and capable of holding a plurality of wafers W in multiple stages is inserted into the processing chamber 301. The wafer boat 305 has three support columns 306 (only two shown in FIG. 6), and the wafers W are held by grooves (not shown) formed in the support columns 306. The wafer boat 305 is configured to simultaneously hold, e.g., fifty to hundred wafers W.

The wafer boat 305 is placed on a rotary table 308 via a tubular body 307 made of quartz. Provided at the opening of the bottom end of the manifold 303 is a bottom cover 309 made of, e.g., stainless steel to perform opening and closing. The rotary table 308 is supported by a rotary shaft 310 provided to extend through the bottom cover 309. For example, a magnetic fluid seal 311 is provided at a through-hole (not shown) of the bottom cover 309 through which the rotary shaft 310 is inserted. The magnetic fluid seal 311 airtightly seals the through-hole of the bottom cover 309 through which the rotary shaft 310 is inserted while allowing rotation of the rotary shaft 310. Further, a seal member 312 such as an 0 ring is provided between the periphery of the bottom cover 309 and the bottom end of the manifold 303, thereby maintaining sealing of the processing chamber 301.

The rotary shaft 310 is attached to the tip of an arm 313. The arm 313 is held by a lifting mechanism (not shown) such as a boat elevator. Accordingly, the wafer boat 305, the rotary table 308 and the bottom cover 309 are lifted as a single unit so that the wafer boat 305 can be inserted into or extracted from the processing chamber 301. Further, the rotary table 308 may be fixed to the bottom cover 309 so that the wafers W can be processed without rotating the wafer boat 305.

The ALD apparatus 300 includes a nitrogen-containing gas supply unit 314 for supplying a nitrogen-containing gas, e.g., N₂ gas or NH₃ gas into the processing chamber 301; a Si-containing compound gas supply unit 315 for supplying a Si-containing compound gas into the processing chamber 301; and a purge gas supply unit 316 for supplying, as a purge gas, an inactive gas, e.g., N₂ gas, into the processing chamber 301. For example, N₂ gas, NH₃ gas or the like may be used as the nitrogen-containing gas. Further, e.g., a silane precursor such as dichlorosilane (DCS; SiH₂Cl₂) may be used as the Si-containing compound.

The nitrogen-containing gas supply unit 314 includes a nitrogen-containing gas supply source 317; a gas supply pipe 318 through which the nitrogen-containing gas is supplied from the nitrogen-containing gas supply source 317; and a dispersion nozzle 319 connected to the gas supply pipe 318. The dispersion nozzle 319 is provided to inwardly extend through a sidewall of the manifold 303, and is formed of a quartz tube bent upward and extending vertically in a longitudinal direction of the processing chamber 301. Gas injection holes 319a are formed at a predetermined interval in a vertical portion of the dispersion nozzle 319. The nitrogen-containing gas, e.g., N₂ gas or NH₃ gas may be substantially uniformly injected in a horizontal direction toward the processing chamber 301 through the gas injection holes 319a.

Further, the Si-containing compound gas supply unit 315 includes a Si-containing compound gas supply source 320; a gas supply pipe 321 through which the Si-containing compound gas is supplied from the Si-containing compound gas supply source 320; and a dispersion nozzle 322 connected to the gas supply pipe 321. The dispersion nozzle 322 is provided to inwardly extend through the sidewall of the manifold 303, and is formed of a quartz tube bent upward and extending vertically in the longitudinal direction of the processing chamber 301. For example, two dispersion nozzles 322 are provided (see FIG. 7), and gas injection holes 322a are formed at predetermined intervals in a vertical portion of each of the dispersion nozzles 322. The Si-containing compound gas may be substantially uniformly injected in a horizontal direction toward the processing chamber 301 through the gas discharge holes 322a. Further, one or three or more dispersion nozzles 322 may be provided without being limited to two dispersion nozzles.

The purge gas supply unit 316 includes a purge gas supply source 323; a gas supply pipe 324 through which a purge gas is supplied from the purge gas supply source 323; and a purge gas nozzle 325 connected to the gas supply pipe 324 and provided to extend through the sidewall of the manifold 303. An inactive gas (e.g., N₂ gas) may be used as the purge gas.

Opening/closing valves 318a, 321a and 324a and flow rate controllers 318b, 321b and 324b such as mass flow controllers are respectively provided in the gas supply pipes 318 321 and 324 to supply the nitrogen-containing gas, the Si-containing compound gas and the purge gas while controlling their flow rates.

A plasma generating unit 330 for generating a plasma of the nitrogen-containing gas is provided in the processing chamber 301. The plasma generating unit 330 has an extension wall 332. A part of the sidewall of the processing chamber 301 is cut out in a predetermined width along a vertical direction, and an opening 331 is formed in a vertically elongated shape. The opening 331 is formed to be sufficiently long in a vertical direction (longitudinal direction of the processing chamber 301) to cover all the wafers W held in multiple stages in the wafer boat 305.

The extension wall 332 is airtightly bonded to the wall of the processing chamber 301 to cover the opening 331 from the outside. The extension wall 332 is formed of, e.g., quartz. The extension wall 332 has a U-shaped transverse cross-section, and is formed to be elongated in a vertical direction (longitudinal direction of the processing chamber 301). By providing the extension wall 332, a part of the sidewall of the processing chamber 301 is formed to extend outward and have a U-shaped transverse cross-section, and an inner space of the extension wall 332 integrally communicates with an inner space of the processing chamber 301.

The plasma generating unit 330 includes a pair of plasma electrodes 333a and 333b each having an elongated shape; a power supply line 334 connected to the plasma electrodes 333a and 333b; and a high frequency power supply 335 for supplying a high frequency power to the pair of plasma electrodes 333a and 333b through the power supply line 334. The pair of elongated plasma electrodes 333a and 333b are respectively arranged on outsides of facing sidewalls 332a and 332b of the extension wall 332 to face each other in a vertical direction (longitudinal direction of the processing chamber 301). Further, a plasma of the nitrogen-containing gas can be generated by applying a high frequency power of, e.g., 13.56 MHz to the plasma electrodes 333a and 333b from the high frequency power supply 335.

Here, the frequency of the high frequency power may be any other frequency, e.g., 400 kHz or the like without being limited to 13.56 MHz.

An insulating protection cover 336 made of, e.g., quartz is attached onto an outside of the extension wall 332 to cover the extension wall 332. Further, a refrigerant passage (riot shown) is provided inside of the insulating protection cover 336 to cool the plasma electrodes 333a and 333b by flowing a refrigerant such as a cooled nitrogen gas therethrough.

The dispersion nozzle 319 through which the nitrogen-containing gas is introduced into the processing chamber 301 is bent outward in a radial direction of the processing chamber 301 after extending upward in the processing chamber 301, and formed to uprightly extend along an outermost wall 332c of the extension wall 332 (farthest from the center of the processing chamber 301). When a high frequency electric field is generated between the plasma electrodes 333a and 333b by the high frequency power supplied from the high frequency power supply 335, N₂ gas or NH₃ gas injected through the gas discharge holes 319a of the dispersion nozzle 319 is converted into a plasma, and the plasma diffuses toward the center of the processing chamber 301.

The two dispersion nozzles 322 through which the Si-containing compound gas is supplied into the processing chamber 301 are uprightly provided in a such way that the opening 331 of the processing chamber 301 is located between the dispersion nozzles 322. The Si-containing compound gas may be injected toward the center of the processing chamber 301 through the gas discharge holes 322a formed in the dispersion nozzles 322.

Meanwhile, an exhaust port 337 is provided on the opposite side to the opening 331 of the processing chamber 301 to vacuum evacuate the processing chamber 301 therethrough. The exhaust port 337 is formed in an elongated shape by cutting a portion of the sidewall of the processing chamber 301 in a vertical direction (longitudinal direction of the processing chamber 301). An exhaust cover 338 having a U-shaped transverse cross-section is joined and attached to the periphery of the exhaust port 337 by, e.g., welding to cover the exhaust port 337. The exhaust cover 338 extends more upward than an upper end of the processing chamber 301 in a longitudinal direction of the processing chamber 301. The exhaust cover 338 is connected to a gas outlet 339 provided above the processing chamber 301. The gas outlet 339 is connected to a vacuum exhaust unit (not shown) including a vacuum pump and configured to vacuum evacuate the processing chamber 301. A housing-shaped heating unit 340 is provided around the processing chamber 301 to surround the processing chamber 301 to heat the processing chamber 301 and the wafers W loaded in the processing chamber 301.

The control of each component of the ALD apparatus 300, e.g., the supply/stop of each gas by opening/closing the valves 318a, 321a and 324a, the control of gas flow rate by the flow rate controllers 318b, 321b and 324b, the on/off control of the high frequency power supply 335, the control of the heating unit 340 or the like is performed by a control unit 70B. Since a basic configuration and function of the control unit 70B are similar to the control unit 50 of the plasma processing apparatus 100 shown in FIG. 1, a description thereof is omitted.

In a modification example, a step of supplying the Si-containing compound gas into the processing chamber 301 and adsorbing the Si-containing compound gas onto the wafer W by the ALD method, and a step of supplying the nitrogen-containing gas into the processing chamber 301 and nitriding the Si-containing compound gas are alternately repeated. Specifically, in the step of adsorbing the Si-containing compound gas onto the wafer W, the Si-containing compound gas is supplied into the processing chamber 301 through the dispersion nozzles 322 for a predetermined period of time. Accordingly, the Si-containing compound gas is adsorbed onto the wafer W.

Then, in the step of supplying the nitrogen-containing gas into the processing chamber 301 and nitriding the Si-containing compound gas, the nitrogen-containing gas is supplied into the processing chamber 301 through the dispersion nozzle 319 for a predetermined period of time. The Si-containing compound gas adsorbed onto the wafer W is nitrided by the nitrogen-containing gas which is converted into a plasma by the plasma generating unit 330, thereby forming a silicon nitride film serving as, e.g., the spacer film 67A.

Further, when switching between the step of adsorbing the Si-containing compound gas onto the wafer W and the step of nitriding the Si-containing compound gas, a step of supplying a purge gas containing an inactive gas such as N₂ gas into the processing chamber 301 while vacuum evacuating the processing chamber 301 may be performed for a predetermined period of time during an interval between the steps in order to remove a residual gas in the previous step. Further, this step may be performed in another way if it is possible to remove the gas remaining in the processing chamber 301. That is, in this step, vacuum evacuation may be performed after stopping the supply of all gases without supplying the purge gas.

The preferred conditions for forming a silicon nitride film at a low temperature by the ALD method using the ALD apparatus 300 are exemplified below.

### Preferred Film Formation Conditions by ALD Method

(1) Si-Containing Gas Supply Conditions

Si-containing gas: dichlorosilane

Substrate (wafer W) temperature: from 300 to 400° C.

Pressure in processing chamber 301: from 27 to 67 Pa

Gas flow rate: from 500 to 2000 mL/min (sccm)

Supply time: from 1 to 30 seconds

(2) Nitrogen-containing gas supply conditions

Nitrogen-containing gas: NH₃ gas

Substrate (wafer W) temperature: from 300 to 400° C.

Pressure in processing chamber 301: from 27 to 67 Pa

Gas flow rate: from 1000 to 10000 mL/min (sccm)

Supply time: from 1 to 30 seconds

Frequency of high frequency power supply: 13.56 MHz

Power of high frequency power supply: from 50 to 500 W

(3) Purge Gas Supply Conditions

Purge gas: N₂ gas

Pressure in processing chamber 301: from 0.133 to 67 Pa

Gas flow rate: from 0.1 to 5000 mL/min (sccm)

Supply time: 1 to 60 seconds

(4) Repeated Condition

Total cycle: from 20 to 50 cycles

As described above, by using the ALD method, the spacer film 67A can be formed at a temperature of 400° C. or lower. Further, by using the ALD method, it is possible to achieve a good step coverage of the spacer film 67A coated on the laminated structure 60A.

### Second Embodiment

In the first embodiment, mainly, modification of the

SiN film used as a spacer film, a liner film, a sidewall film, a cap film or the like of a semiconductor device has been described as an example. However, the plasma-nitriding method of the present invention may be applied for other purposes. For example, when a device isolation film is formed by shallow trench isolation (STI), after a SiN film is formed on an inner surface of a silicon trench by the ALD method, a SiO₂ film may be embedded as a device isolation film in the trench. In this case, oxygen in the embedded SiO₂ film reaches an interface between the SiN film and silicon through the SiN film, and reacts with silicon to form SiO₂. The SiN film is converted into a SiON film to substantially grow the film.

As a result, a device formation region becomes small, and it is impossible to stably manufacture a device, thereby reducing a yield. In order to avoid such problems, the plasma-nitriding process may be performed on the SiN film formed on the inner surface of the trench by the ALD method under the same conditions as the first embodiment in the plasma processing apparatus 100. The SiN film formed on the inner surface of the trench by the ALD method is modified and becomes dense by the plasma-nitriding process. Accordingly, even if the SiO₂ film is embedded in the trench, oxygen can be prevented from diffusing into the interface between the SiN film and silicon, thereby preventing a film growth.

### Test Example

Next, Test data for confirming the effect of the present invention will be described. A SiN film was formed on a silicon substrate at a film forming temperature of 400° C. or 630° C. by the ALD method using dichlorosilane as a precursor (hereinafter, respectively referred to as “400° C.-ALD film” and “630° C.-ALD film”). The 400° C.-ALD film was modified by the plasma-nitriding process under the following conditions A or conditions B (hereinafter, respectively referred to as “modified SiN film A” and “modified SiN film B”). Then, each SiN film was immersed in 0.5 wt % dilute hydrofluoric acid solution for 1 minute. A wet etching rate per minute was calculated from a difference in thickness before and after immersion.

(Conditions A: Formation of Modified SiN Film A)

Ar gas flow rate: 1000 mL/min (sccm)

N₂ gas flow rate: 200 mL/min (sccm)

Processing pressure: 20 Pa

Temperature of mounting table: 400° C.

Microwave power: 1500 W (power density: about 0.8 W/cm²)

Processing time: 180 seconds

(Conditions B: Formation of Modified SiN Film B)

He gas flow rate: 1000 mL/min (sccm)

N₂ gas flow rate: 200 mL/min (sccm)

Processing pressure; 20 Pa

Temperature of mounting table: 400° C.

Microwave power: 1500 W (power density: about 0.8 W/cm²)

Processing time: 180 seconds

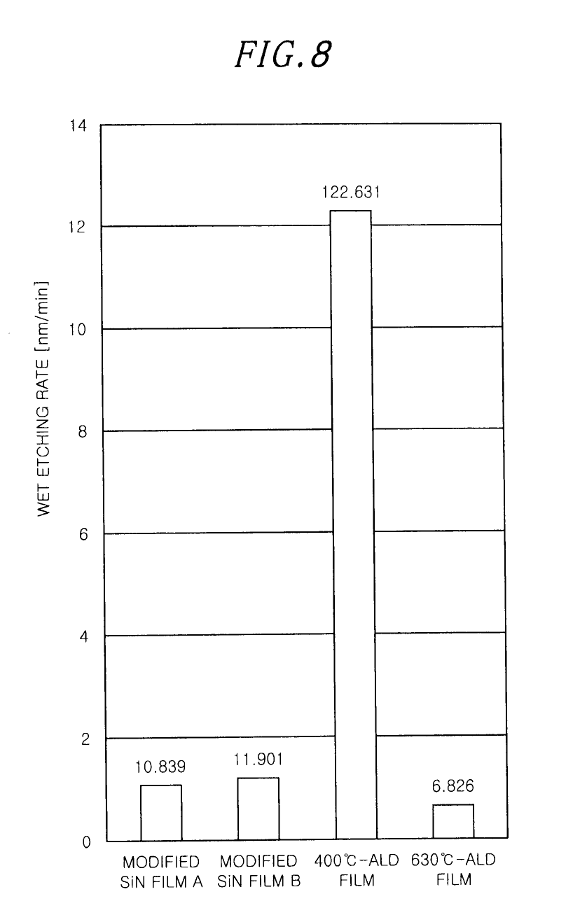

FIG. 8 shows the experimental results. In FIG. 8, the vertical axis represents the wet etching rate, and the horizontal axis represents the respective samples. It can be seen from FIG. 8 that the wet etching rate is extremely high in the 400° C.-ALD film compared to the 630° C.-ALD film. However, in both of the modified SiN film A and the modified SiN film B that have been modified by the plasma-nitriding method of the present invention, the wet etching rate was significantly reduced to a level close to that of the 630° C.-ALD film.

Further, comparing the modified SiN film A with the modified SiN film B, the similar modification effect was obtained for both of Ar gas and He gas serving as a rare gas for plasma generation.

It can be seen from the above test results that the quality of the SiN film formed by the ALD method at a low temperature of 400° C. can be significantly improved, and the resistance to wet etching can be improved by the plasma-nitriding method of the present invention. Further, it can be seen that in the plasma-nitriding method of the present invention, a sufficient modification effect can be obtained even at a low temperature of 400° C., which is the same temperature as the film forming temperature of the SiN film formed by the ALD method.

Although the embodiments of the present invention have been described, the present invention is not limited to the above embodiments, and various modifications may be made. For example, a substrate to be processed is not limited to a semiconductor wafer, and may be, e.g., a substrate for flat panel displays or substrate for solar cells.

In accordance with the plasma-nitriding method of the aspect of the present invention, the silicon nitride film formed by the ALD method is modified by the nitrogen-containing plasma at a temperature that is equal to or lower than its film forming temperature, thereby forming the silicon nitride film with an improved denseness. Since the modified silicon nitride film has a high resistance to wet etching, it is possible to suppress a reduction in the silicon nitride film even if the wet etching is performed during the semiconductor process. Further, since the silicon nitride film becomes dense by the modification, it is possible to prevent diffusion of oxygen. Furthermore, since the plasma-nitriding process is performed at a processing temperature that is equal to or lower than the maximum of the ALD method, it is possible to reduce the thermal budget. Thus, the plasma-nitriding method in accordance with the aspect of the present invention is applied in a process of manufacturing various semiconductor devices, thereby enhancing the reliability of a semiconductor device.

What is claimed is:

1. A plasma-nitriding method for plasma-nitriding a silicon nitride film by using a plasma processing apparatus which includes:
a processing chamber having an opening at its top;
a mounting table, for mounting a target object having the silicon nitride film thereon, provided in the processing chamber;
a heating unit for heating the target object;
a microwave transmitting plate provided to face the mounting table, the microwave transmitting plate serving to close the opening of the processing chamber and transmit a microwave therethrough;
a planar antenna disposed outside the microwave transmitting plate and having slots through which the microwave is introduced into the processing chamber;
a gas inlet configured to introduce a processing gas into the processing chamber; and
an exhaust unit configured to vacuum evacuate the processing chamber,
the method comprising:
loading the target object into the processing chamber and mounting the target object on the mounting table;
heating the target object by the heating unit;
supplying a processing gas including a nitrogen-containing gas and a rare gas into the processing chamber from the gas inlet while introducing the microwave into the processing chamber from the planar antenna through the microwave transmitting plate, generating an electric field in the processing chamber, and generating a plasma by exciting the processing gas; and
plasma-nitriding and modifying the silicon nitride film formed on the target object by the generated plasma of the processing gas,
wherein the silicon nitride film is a silicon nitride film formed at a film forming temperature ranging from 200° C. to 400° C. by an ALD method, and the silicon nitride film is plasma-nitrided at a processing temperature whose maximum is equal to the film forming temperature in the ALD method to form a silicon nitride film modified by a low-temperature nitrogen-containing plasma.

2. The plasma-nitriding method of claim 1, wherein a processing pressure in the plasma-nitriding ranges from 1.3 Pa to 67 Pa, and a ratio of a volumetric flow rate of the nitrogen-containing gas to a total volumetric flow rate of the processing gas ranges from 5% to 30%.

3. The plasma-nitriding method of claim 1, wherein a power density of the microwave ranges from 0.5 W/cm² to 2.5 W/cm² per area of the microwave transmitting plate.

4. The plasma-nitriding method of claim 2, wherein a power density of the microwave ranges from 0.5 W/cm² to 2.5 W/cm² per area of the microwave transmitting plate.
